(19) United States
(12) Patent Application Publication
(10) Pub. No.: US 2016/0249450 A1
(43) Pub. Date: Aug. 25, 2016

(54) CIRCUIT BOARD AND MANUFACTURING METHOD THEREOF

(71) Applicant: SAMSUNG ELECTRO-MECHANICS CO., LTD., Suwon-si (KR)

(72) Inventors: Tae-Hong MIN, Hwaseong-si (KR); Myung-Sam KANG, Hwaseong-si (KR); Jin-Hyuk JANG, Hanam-si (KR); Young-Gwan KO, Seoul (KR)

(73) Assignee: SAMSUNG ELECTRO-MECHANICS CO., LTD., Suwon-si (KR)

(21) Appl. No.: 15/000,398

(22) Filed: Jan. 19, 2016

(30) Foreign Application Priority Data
Feb. 23, 2015 (KR) 10-2015-0025165

(51) Int. Cl. H05K 1/02; H05K 3/40; H05K 1/18; H05K 1/11; H05K 1/03

(52) U.S. Cl. CPC H05K 1/0298; H05K 1/115; H05K 1/0306; H05K 1/183; H05K 3/4038

(57) ABSTRACT

A circuit board and a related manufacturing method are disclosed. The circuit board includes a core part that includes a first core layer that is formed of graphite or graphene material and that has a through hole that penetrates from one surface through to the other surface of the first core layer, and a second core layer and a third core layer that are formed of a metallic material and disposed respectively on the one surface and the other surface of the first core layer. The through hole is filled with the metallic material that forms the second core layer and the third core layer.

CROSS-REFERENCE TO RELATED APPLICATION(S)

This application claims the benefit under 35 USC 119(a) of Korean Patent Application No. 10-2015-0025165 filed on Feb. 23, 2015 in the Korean Intellectual Property Office, the entire disclosure of which is incorporated herein by reference for all purposes.

### BACKGROUND

1. Field

The following description relates to a circuit board. The following description also relates to a method of manufacturing such a circuit board.

2. Description of Related Art

In accordance with a trend toward light weight, miniaturization, increased speed, multi-functional capabilities, and operational improvement in functional performance of electronic devices, multilayered substrate technologies in which a plurality of wiring layers are formed on a printed circuit board (PCB) have been developed. Furthermore, technologies in which electronic components such as active elements, passive elements, or other appropriate electronic elements, are embedded in a multilayered substrate have also been developed.

As an application processor (AP) that is connected to the multilayered substrate becomes multi-functional and achieves high performance, the heat generation amount of such an AP potentially increases significantly.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a circuit board includes a core part, including a first core layer, formed of graphite or graphene material and comprising a through hole that penetrates from one surface of the first core layer through to the other surface of the first core layer, and a second core layer and a third core layer, each formed of a metallic material and respectively situated on the one surface and the other surface of the first core layer, wherein the through hole is filled with the metallic material that forms the second core layer and the third core layer.

A through via that penetrates through the core part from the one surface to the other surface may penetrate through an inner side of the through hole.

A circuit pattern may be situated on the one surface or the other surface of the core part, and an insulation layer may be interposed between an outer surface of the through via and a surface of the core part and between an outer surface of the circuit pattern and the surface of the core part.

The through hole may include a first through hole through which the through via penetrates and a second through hole through which the through via does not penetrate.

A via that penetrates through the second core layer or the third core layer may be situated accordingly, and an insulation layer may be interposed between a surface of the via and the core part.

At least a portion of a side wall on a perimeter of the first core layer may be exposed through the second core layer and the third core layer.

At least a portion of a side wall on a perimeter of the first core layer may be covered by the metallic material that forms the second core layer and the third core layer.

A cavity may penetrate through the core part from the one surface to the other surface and at least a portion of a first electronic component may be embedded in the cavity.

At least a portion of a side wall on a perimeter of the first electronic component may be disposed to face the cavity, and the insulation layer may be interposed between the first electronic component and the cavity.

A primer layer may be situated on the surface of the first core layer.

The first core layer may be provided using a unit structure that is formed by disposing a primer layer on a surface of graphite or graphene.

In another general aspect, a method of manufacturing a circuit board includes providing a first core layer that is formed of graphite or graphene material and has a through hole that penetrates from one surface through to the other surface, forming a core part by forming a second core layer and a third core layer by providing a metallic material on the one surface and the other surface of the first core layer in order to fill an inside of the through hole with the metallic material, forming a through via hole that penetrates the core part from the one surface to the other surface penetrates through an inner side of the through hole, forming an insulation layer on an inner side wall of the through via hole, and forming a through via by filling the through via ,hole with a conductor.

The method may further include forming a via hole that penetrates through the second core layer or the third core layer to expose the first core layer.

The through hole may include a first through hole through which the through via penetrates and a second through hole through which the through via does not penetrate.

The method may further include forming a cavity on the core part.

Other features and aspects will be apparent from the following detailed description, the drawings, and the claims.

### BRIEF DESCRIPTION OF THE DRAWINGS

FIG. 1 is a view illustrating a circuit board 100 according to an example.

FIG. 2 is a view illustrating a circuit board 100 according to another example.

FIG. 3 is a view illustrating an example of the first core layer 11′ that is applied to the circuit board 100, according to an example.

FIG. 4 is a view illustrating another example of the first core layer 11″, according to an example.

FIG. 5A illustrates a method for manufacturing the circuit board 100 according to an example and shows that the first core layer is formed.

FIG. 5B illustrates a method for manufacturing the circuit board 100 according to an example and shows that the second core layer and the third core layer are formed.

FIG. 5C illustrates a method for manufacturing the circuit board 100 according to an example and shows that through via hole, via hole, and cavity are formed.

FIG. 5D illustrates a method for manufacturing the circuit board 100 according to an example and shows that the insulation layer is formed.

FIG. 5E illustrates a method for manufacturing the circuit board 100 according to an example and shows that the first electronic component is inserted and the through via and via are formed.

FIG. 5F illustrates a method for manufacturing the circuit board 100 according to an example and shows that the first upper insulation layer and the first lower insulation layer are formed.

FIG. 5G illustrates a method for manufacturing the circuit board 100 according to an example and shows that the second upper insulation layer and the second lower insulation layer are formed.

FIG. 6A illustrates a method of manufacturing the circuit board 100 according to another example and shows that the first core layer is formed.

FIG. 6B illustrates a method of manufacturing the circuit board 100 according to another example and shows that the second core layer and the third core layer are formed.

FIG. 6C illustrates a method of manufacturing the circuit board 100 according to another example and shows that a through via hole, a via hole, and a cavity are formed.

FIG. 6D illustrates a method of manufacturing the circuit board 100 according to another example and shows that the insulation layer is formed.

FIG. 6E illustrates a method of manufacturing the circuit board 100 according to another example and shows that the first electronic component is inserted and the through via and the via hole are formed.

FIG. 6F illustrates a method of manufacturing the circuit board 100 according to another example and shows that the first upper insulation layer and the first lower insulation layer are formed.

FIG. 6G shows that the second upper insulation layer and the second lower insulation layer are formed.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Hereinafter, examples are described in further detail. However, the present invention is not limited to the examples disclosed below but is potentially implemented in various forms. The following examples are described in order to enable those of ordinary skill in the art to embody and practice the present invention. To clearly describe the present invention, parts not relating to the description are omitted from the drawings for brevity. Like numerals refer to like elements throughout the description of the drawings.

Terms used herein are provided for explaining examples, and are not intended as being limiting. As used herein, the singular forms “a”, “an” and “the” are intended to include the plural forms as well, unless the context clearly indicates otherwise. It is to be further understood that the terms “comprises” and/or “comprising,” when used in this specification, are used to specify the presence of stated components, motions, and/or devices, but do not preclude the presence or addition of one or more other components, motions, and/or devices thereof.

It is to be understood that, although the terms “first,” “second,” “third,” “fourth” etc. may be used herein to describe various elements, these elements should not be limited by these terms. These terms are only used to distinguish one element from another. For example, a first element could be termed a second element, and, similarly, a second element could be termed a first element, without departing from the scope of the present invention. Similarly, when it is described that a method includes series of steps, a sequence of the steps is not a sequence in which the steps should be performed in the sequence, an arbitrary technical step may be omitted and/or another arbitrary step, which is not disclosed herein, may be added to the method.

It is to be understood that when terms “left,” “light,” “front,” “rear,” “on,” “under,” “over,” “beneath” or the like are used, the terms are merely used for the purpose of description, not to describe unchangeable relative positions. Hence, such terms used herein are possibly variable so as to be operated in different directions and orientations that are shown and described herein under an appropriate environment. It is also to be understood that when an element is referred to as being “connected” or “coupled” to another element, such an element is possibly directly connected or coupled to the other element or intervening elements may be present. By contrast, when an element is referred to as being “directly connected” or “directly coupled” to another element, there are no intervening elements present. Also, the phrase “in one example” means that a feature is present in that particular example, but does not require that the feature is present in all examples unless that is expressly stated.

Subsequently, configurations of and results achieved by the present examples are described in further detail with reference to the accompanying drawings.

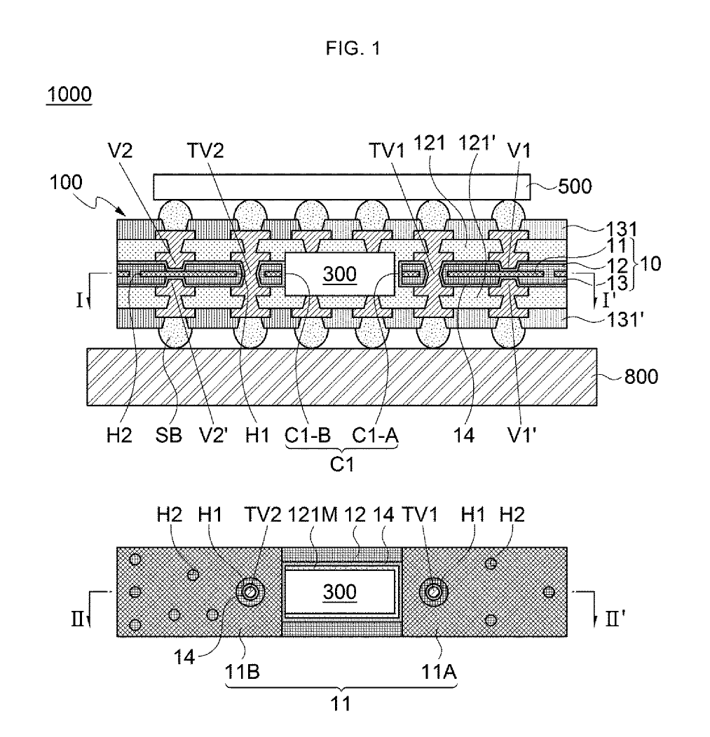

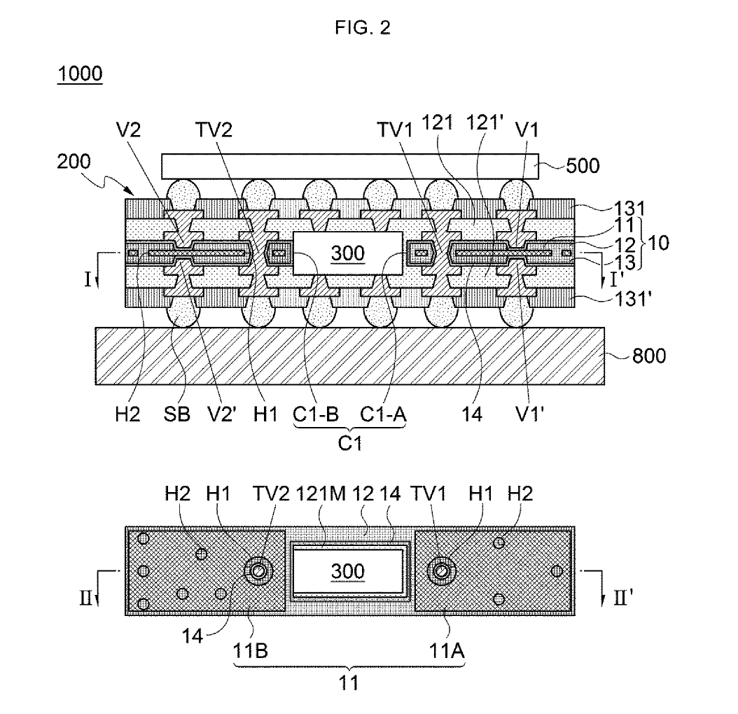

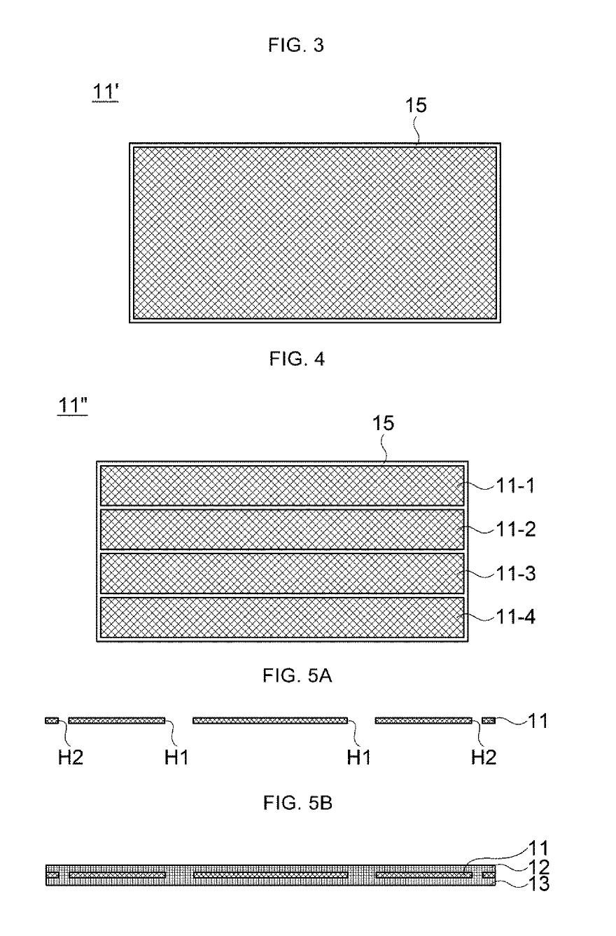

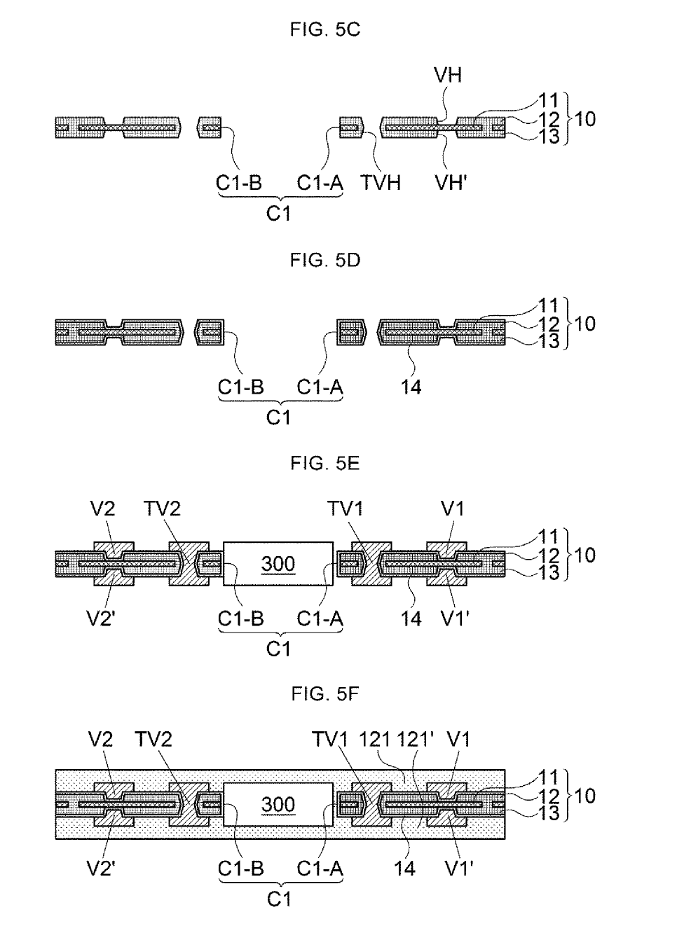

FIG. 1 is a view illustrating a circuit board 100 according to one example. FIG. 2 is a view illustrating a circuit board 200 according to another example. FIG. 3 is a view illustrating one example of the first core layer 11′ that is applied to the circuit board 100 according to one example. FIG. 4 is a view illustrating another example of the first core layer 11″ according to one example.

Referring to FIGS. 1 through 4, the circuit board 100 according to an example includes a core part 10. In these examples, an insulation layer and a circuit pattern layer are disposed on the core part 10, and are optionally formed in a plurality of layers, if required.

In one example, the core part 10 includes a first core layer 11, a second core layer 12, and a third core layer 13. In such an example, the first core layer 11 is formed of a graphite or a graphene material, and the second core layer 12 and the third core layer 13 are formed of a metallic material such as a copper (Cu) material. However, these are merely examples and other materials with appropriate physical properties are potentially used instead.

In certain approaches, graphite or graphene is formed in a plate shape structure in which carbon atoms are connected to each other, and these plate shape structures are stacked in a plurality of layers. In such an approach, a plane in which carbons form the plate shape structure is referred to as an XY plane, and a direction in which a plurality of plate shape structures are stacked is referred to as a Z-axis direction. Graphite or graphene has relatively high heat conductivity compared to any metallic material such as copper. Also, in such an approach, graphite or graphene has additional higher heat conductivity in an XY plane direction than in a Z-axis direction.

Accordingly, in an example that an XY plane of graphite or graphene that forms the first core part is directed along a horizontal direction, heat that is generated at one point of the circuit board is possibly dissipated rapidly to entire region of the circuit board, and thus a heat dissipation characteristic of the circuit board is improved. In addition, in an example that an XY plane of graphite or graphene that forms the first core part is directed along a vertical direction, heat is also transferred rapidly in a direction from a top surface of the circuit board to a bottom surface or in a reverse direction, that is, from a bottom surface to a top surface.

In addition, the graphite or graphene that forms the first core layer has relatively low hardness compared to the metallic material that forms the other layers. Especially in an example using graphite or graphene that is formed from the stacked plate shape structures, a bonding power between stacked plates is relatively low. Furthermore, since the first core layer that is formed of graphite or graphene and the second and the third core layers that are formed of the metallic material differ in their materials, the bonding power on the boundary surface is potentially relatively weak.

However, in the circuit board 100 according to one example, the second core layer 12 and the third core layer 13 that are formed of the metallic material are located on one surface and the other surface of the first core layer 11. Also, this metallic material is filled into the interior of a through hole that penetrates the first core layer 11.

As illustrated in the examples of FIGS. 1 through 4, a through hole is formed on the first core layer 11. In these examples, the second core layer 12 and the third core layer 13 are integrally coupled to each other through the through hole, in order to firmly support the first core layer 11. Accordingly, the bonding power between the plate shape structures of graphite or graphene is improved, and additionally the bonding power on the boundary surface to the second core layer 2 and the third core layer 13 that are made of different materials is also improved.

In one example, through vias TV1, TV2 that penetrate the core part 10 are provided. For example, a plurality of through vias TV1, TV2 are provided, and at least one of the plurality of through vias TV1, TV2 passes through the through hole. In such an example, a plurality of the through holes is also potentially provided, and the through hole that the through vias TV1, TV2 pass through potentially has a diameter larger than that of the through vias TV1, TV2.

There is no specific limitation to the diameter of through hole that through vias TV1, TV2 do not pass through. However, by making the diameter of such a through hole smaller than that of the through holes that the through vias TV1, TV2 pass through, a heat transfer performance of the first core layer 11 is potentially maximized while the reliability of the core part 10 is still ensured. In the examples of FIGS. 1 through 4, the through hole that through vias TV1, TV2 pass through is labeled as H1, and the through hole that through vias TV1, TV2 do not pass through is labeled as H2.

In one example, the core part 10 is provided with vias V1, V1′, V2, and V2′ that penetrate the second core layer 12 or the third core layer 13 rather than the first core layer 10. These vias contact the first core layer 11 that is formed of graphite or graphene. As a result of such placement of these vias, the heat transfer performance of the first core layer 11 may be improved.

In one example, circuit patterns are disposed on at least a portion of one surface and the other surface of the core part 10. Furthermore, a portion of these circuit patterns potentially contact the previously mentioned through vias TV1, TV2 or the other vias.

The second core layer 12 and the third core layer 13 are formed of the metallic material. Thus, in an example in which an outer surface of the second core layer 12 or the third core layer 13 contacts conductor patterns directly, an unnecessary electrical connection is made. Thus, the circuit board 100 according to one example is provided with an insulation film 14 that is interposed between the second core layer 12 or the third core layer 13 and the conductor patterns. In this example, the conductor pattern is one of the aforementioned through vias TV1, TV2, or another of the vias, and circuit patterns. In one example, the insulation film 14 is formed by vapor deposition that deposits parylene on the surfaces of the core part 10. Here, parylene is a chemical vapor deposited polymer that acts as a barrier material. That is, during a time period in which through via holes TVH for forming through vias TV1, TV2 are formed in the core part 10, the insulation film 14 is formed on an inner side wall of the through via hole TVH by providing an insulating material on exposed surfaces of the core part 10. Accordingly, the insulating property between through vias TV1, TV2, or other vias and the core part 10 and between circuit patterns and the core part 10 is secured.

In such examples, a cavity C1 is formed in the interior of core part 10 and the first electronic component 300 is inserted into cavity C1. For example, the first electronic component 300 is an active element or a passive element, or another appropriate type of electronic element. Also, the first electronic component 300 is potentially a structure that is formed of a material that has high thermal conductivity so as to perform a heat transfer function.

In one example, in a case in which the first electronic component 300 is the structure configured for performing the heat transfer function, by contacting a side wall of the first electronic component 300 with an inner side wall of cavity C1 in the core part 10, a heat that the first electronic component 300 generates is dissipated rapidly in a horizontal direction through the core part 10.

In this example, in order to provide the insulating property between the first electronic component 300 and the core part 10, the previously mentioned insulation film 14 is disposed on a surface of cavity C1.

As shown in FIG. 1, in one example, a side wall on a perimeter of the first core layer 11 is exposed to the second core layer 12 and the third core layer 13. Also, when the first electronic component 300 is in contact with the first core layer 11 that is exposed on an outer side of the core part 10, the heat that the first electronic component 300 generates is dissipated rapidly through the first core layer 11.

Alternatively, as shown in the example of FIG. 2, in another example, the side wall on the perimeter of the first core layer 11 is covered by the metallic material that forms the second core layer 12 and the third core layer 13. In this example, as compared to the example as illustrated in FIG. 1, although an efficiency of heat exchange decreases, the bonding power of the first core layer 11 itself or the bonding power between the first core layer 11 and the second and the third core layers 12, 13 increases accordingly.

For the convenience of explanation, FIGS. 1 and 2 show a horizontal cross-sectional view as well as a vertical cross-sectional view. The horizontal cross-sectional view is taken along line I-I′ and the vertical cross-sectional view is taken along line II-II′.

In these examples, at least one insulation layer and circuit pattern layer are disposed on the outer side of the core part 10. Also, in an example, an electronic component 500, such as an integrated circuit, is embedded in at least one surface of the circuit board 100, and the circuit board 100 is mounted on an additional board 800 such as a main board.

For example, the insulation layer that is disposed on an upper portion of the core part 10 is referred to as the first upper insulation layer 121. The insulation layer that is disposed on a lower portion of the core part 10 is referred to as the first lower insulation layer 121′. The material that forms the first upper insulation layer 121 and the first lower insulation layer 121′ is filled in between cavity C1 and the first electronic component 300. For example, in the examples of FIGS. 1 and 2, the material that is filled in between the first electronic component 300 and cavity C1 is denoted as 121M.

In the example in which the first electronic component 300 performs the heat transfer function, the heat that the electronic component 500 generates is transferred to the additional board 800 through the first electronic component 300. The heat is also potentially dissipated in a horizontal direction through the core part 10.

In addition, even if the first electronic component 300 is provided in an example as a passive element, such as multi-layer ceramic capacitor (MLCC), so that the heat transfer function is not performed smoothly, the heat that the electronic component 500 generates is potentially transferred to the core part 10 through the circuit pattern and vias, and is dissipated through the core part 10. Here, an MLCC is a fixed value capacitor in which ceramic material acts as the dielectric.

As a result of such an approach, the heat dissipation of the circuit board 100 is improved.

Referring to the example of FIG. 3, a primer layer 15 is situated on an outer surface of the first core layer 11′. By situating the primer layer 15 on the outer surface of the first core layer 11′ that is formed of a graphite sheet or a graphene sheet, the inter-layer bonding power is increased. Also, the primer layer 15 increases not only the inter-layer bonding power between graphite or graphene that forms the first core layer 11′ but also the inter-layer bonding power between the first core layer 11′ and the second core layer 12 and between the first core layer 11′ and the third core layer 13.

In another example, referring to FIG. 4, the first core layer 11″ is made by using stacking unit structures. These stacking unit structures are formed by situating the primer layer 15 on the surface of a graphite or graphene sheet, in the vertical direction. This approach minimizes a decrease in the horizontal heat dissipation of the first core layer 11″. Such an approach also relieves a delamination of the first core layer 11″ in the vertical direction.

In an example, the primer layer 15 is formed of a primer including Iso-Propyl alcohol and acryl-based silane. A silane is a type of coupling agent that is effective for bonding organic and inorganic materials, and hence is effective for bonding a metal with a carbon-based sheet as discussed above. Also, in another example, the primer layer 15 is formed of MPS (3-(trimethoxysilyl)propylmethacrylate), and a silane-based additive is added to the primer layer 15.

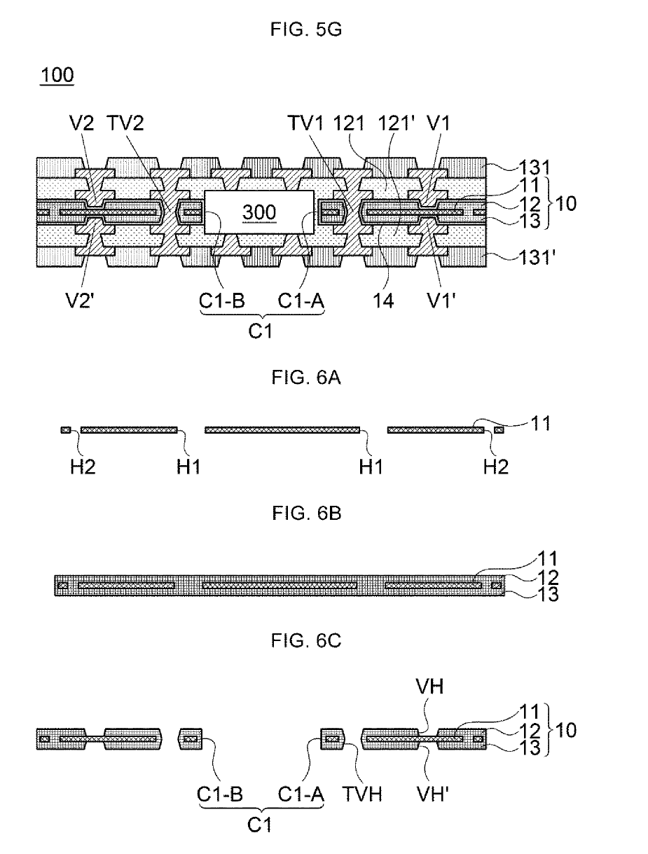

FIGS. 5A through 5G illustrate the method of manufacturing the circuit board 100, according to one example.

Referring to the example of FIG. 5A, the first core layer 11 that is formed of graphite or graphene is provided. The first core layer 11 may include at least one through hole.

Referring to the example of FIG. 5B, the second core layer 12 and the third core layer 13 are formed by providing a metallic material to the first core layer 11. The metallic material is provided in various examples by various methods such as a printing method, a plating method, or another similar appropriate method, and the second core layer 12 and the third core layer 13 are connected to each other in an integrated fashion by filling in the through hole with the metallic material.

Referring to the example of FIG. 5C, the through via hole TVH, the via hole VH, and cavity C1 are formed on the core part 10.

Referring to the example of FIG. 5D, the insulation layer 14 is formed on the exposed surface of the core part 10.

Referring to the example of FIG. 5E, the through vias TV1, TV2, vias, and circuit patterns are formed on the core part 10. The first electronic component 300 is inserted in cavity C1.

Referring to the example of FIG. 5F, the first upper insulation layer 121 and the first lower insulation layer 121′ that cover the core part 10 and the first electronic component 300 are formed.

Referring to the example of FIG. 5G, the second upper insulation layer 131 and the second lower insulation layer 131′ are further formed.

Although not shown, in an example, the electronic component 500 is embedded in the upper surface of the circuit board 100, and the circuit board 100 is potentially mounted on the additional board 800. In this step, a solder ball is possibly used, but embedding techniques are not limited to the solder ball.

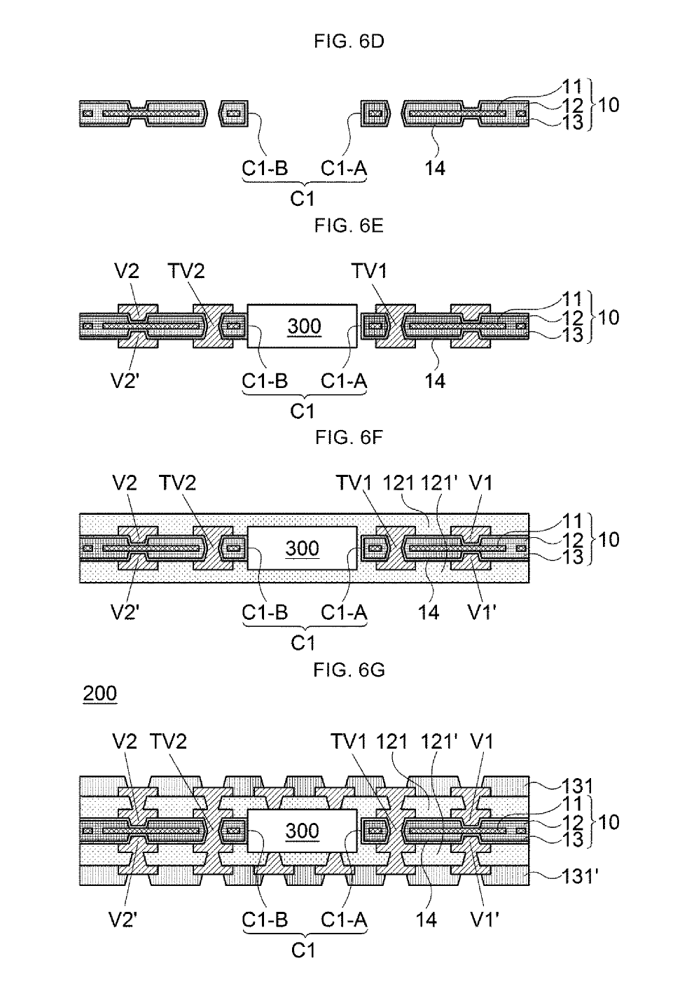

FIGS. 6A through 6G illustrate the method of manufacturing the circuit board 200 according to another example. Other than that in the examples of FIGS. 6A through 6G at least a portion of side wall on a perimeter of the first core layer 11 is covered by the metallic material that forms the second core layer 12 and the third core layer 13, these examples are the same as the aforementioned examples and accordingly a corresponding description is omitted here for brevity.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board, comprising:
a core part, comprising
a first core layer, formed of graphite or graphene material and comprising a through hole that penetrates from one surface of the first core layer through to the other surface of the first core layer, and
a second core layer and a third core layer, each formed of a metallic material and respectively situated on the one surface and the other surface of the first core layer,
wherein the through hole is filled with the metallic material that forms the second core layer and the third core layer.

2. The circuit board of claim 1, wherein a through via that penetrates through the core part from the one surface to the other surface penetrates through an inner side of the through hole.

3. The circuit board of claim 2, wherein a circuit pattern is situated on the one surface or the other surface of the core part, and
wherein an insulation layer is interposed between an outer surface of the through via and a surface of the core part and between an outer surface of the circuit pattern and the surface of the core part.

4. The circuit board of claim 2, wherein the through hole comprises a first through hole through which the through via penetrates and a second through hole through which the through via does not penetrate.

5. The circuit board of claim 1, wherein a via that penetrates through the second core layer or the third core layer is situated accordingly, and wherein an insulation layer is interposed between a surface of the via and the core part.

6. The circuit board of claim 1, wherein at least a portion of a side wall on a perimeter of the first core layer is exposed through the second core layer and the third core layer.

7. The circuit board of claim 1, wherein at least a portion of a side wall on a perimeter of the first core layer is covered by the metallic material that forms the second core layer and the third core layer.

8. The circuit board of claim 1, wherein a cavity penetrates through the core part from the one surface to the other surface and at least a portion of a first electronic component is embedded in the cavity.

9. The circuit board of claim 8, wherein at least a portion of a side wall on a perimeter of the first electronic component is disposed to face the cavity, and the insulation layer is interposed between the first electronic component and the cavity.

10. The circuit board of claim 1, wherein a primer layer is situated on the surface of the first core layer.

11. The circuit board of claim 1, wherein the first core layer is provided using a unit structure that is formed by disposing a primer layer on a surface of graphite or graphene.

12. A method of manufacturing a circuit board, comprising:
providing a first core layer that is formed of graphite or graphene material and has a through hole that penetrates from one surface through to the other surface;
forming a core part by forming a second core layer and a third core layer by providing a metallic material on the one surface and the other surface of the first core layer in order to fill an inside of the through hole with the metallic material;
forming a through via hole that penetrates the core part from the one surface to the other surface penetrates through an inner side of the through hole;
forming an insulation layer on an inner side wall of the through via hole; and
forming a through via by filling the through via hole with a conductor.

13. The method of claim 12, further comprising forming a via hole that penetrates through the second core layer or the third core layer to expose the first core layer.

14. The method of claim 12, wherein the through hole comprises a first through hole through which the through via penetrates and a second through hole through which the through via does not penetrate.

15. The method of claim 12, further comprising forming a cavity on the core part.
